(19) United States
(12) Patent Application Publication
(10) Pub. No.: US 2017/0062450 A1
(43) Pub. Date: Mar. 2, 2017

(54) NON-VOLATILE MEMORY DEVICE AND METHOD FOR MANUFACTURING SAME

(71) Applicant: Kabushiki Kaisha Toshiba, Minato-ku (JP)

(72) Inventors: Ryota SUZUKI, Yokkaichi (JP); Wataru SAKAMOTO, Yokkaichi (JP)

(73) Assignee: Kabushiki Kaisha Toshiba, Minato-ku (JP)

(21) Appl. No.: 15/011,862

(22) Filed: Feb. 1, 2016

Related U.S. Application Data
(60) Provisional application No. 62/212,831, filed on Sep. 1, 2015.

(51) Int. Cl. H01L 27/115; G11C 16/04; H01L 21/268

(52) U.S. Cl. CPC H01L 27/11531; H01L 27/11524; H01L 21/268; G11C 16/0408

(57) ABSTRACT

A non-volatile memory device comprises a first semiconductor layer extending in a first direction, a first electrode extending over the first semiconductor layer in a second direction crossing the first direction, a second electrode extending over the first semiconductor layer in the second direction, the second electrode being adjacent to the first electrode, a first insulating layer covering the first electrode and the second electrode, and a first interconnection provided on the first insulating layer and electrically connected to the first semiconductor layer. A first insulating layer includes a first portion extending between the first electrode and the second electrode; and the first interconnection has a first opening provided above a first part of the first semiconductor layer located below the first portion of the first insulating layer.

### CROSS-REFERENCE TO RELATED APPLICATIONS

This application is based upon and claims the benefit of priority from U.S. Provisional Patent Application 62/212,831 filed on Sep. 1, 2015; the entire contents of which are incorporated herein by reference.

### FIELD

Embodiments are generally related to a non-volatile memory device and a method for manufacturing the same.

### BACKGROUND

The NAND memory device is one of non-volatile memory devices, which includes a plurality of memory transistors and select transistors sharing one semiconductor layer. Such a memory transistor includes a floating gate that acts as a charge storing part provided between the semiconductor layer and a word line. Each select transistor includes a gate structure similar to the memory transistor, but a floating gate provided between the semiconductor layer and a select gate is electrically connected to the select gate in order to suppress a change of the threshold voltage thereof. In the highly integrated NAND memory device, however, it is difficult to provide the electrical connection between the select gate and the floating gate.

### BRIEF DESCRIPTION OF THE DRAWINGS

FIGS. 1A to 1C are schematic views showing a non-volatile memory device according to an embodiment;

FIGS. 2A and 2B are schematic plan views showing an interconnection of the non-volatile memory device according to the embodiment;

FIGS. 3A to 8 are schematic sectional views showing a manufacturing process of the non-volatile memory device according to the embodiment;

FIGS. 9A and 9B are graphs showing the characteristics of the non-volatile memory device according to the embodiment; and

FIG. 10 is a schematic plan view showing other interconnection of the non-volatile memory device according to the embodiment.

### DETAILED DESCRIPTION

According to an embodiment, a non-volatile memory device comprises a first semiconductor layer extending in a first direction, a first electrode extending over the first semiconductor layer in a second direction crossing the first direction, a second electrode extending over the first semiconductor layer in the second direction, the second electrode being adjacent to the first electrode, a first insulating layer covering the first electrode and the second electrode, and a first interconnection provided on the first insulating layer and electrically connected to the first semiconductor layer. A first insulating layer includes a first portion extending between the first electrode and the second electrode; and the first interconnection has a first opening provided above a first part of the first semiconductor layer located below the first portion of the first insulating layer.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

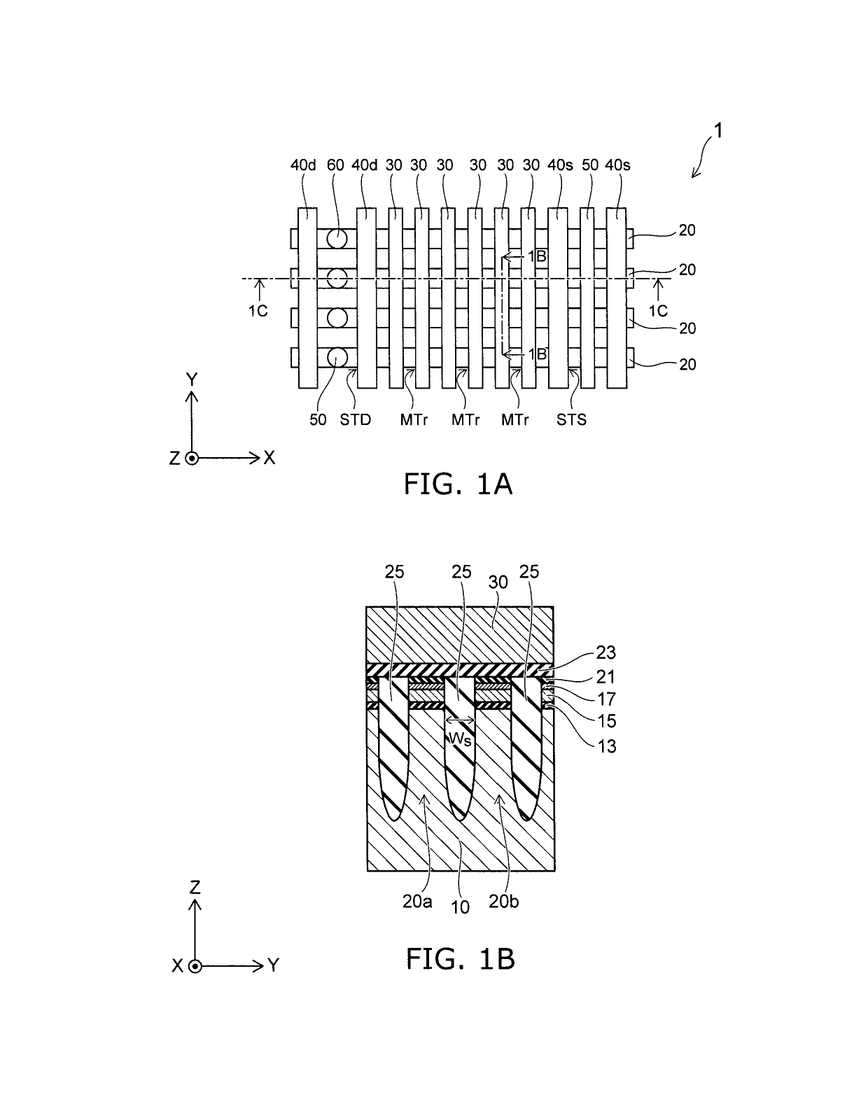

FIGS. 1A to 1C are schematic views showing a non-volatile memory device 1 according to an embodiment. FIG. 1A is a schematic plan view showing the memory cell array of the non-volatile memory device 1. FIG. 1B is a sectional view taken along line 1B-1B shown in FIG. 1A. FIG. 1B shows the structure of the memory transistor MTr. FIG. 1C is a sectional view taken along line 1C-1C shown in FIG. 1A.

The non-volatile memory device 1 is provided, for example, on a silicon substrate. As shown in FIG. 1A, the non-volatile memory device 1 includes semiconductor layers 20, a first electrode (hereinafter, a word line 30), a second electrode (hereinafter, a select gate 40s), and a third electrode (hereinafter, a select gate 40d). The semiconductor layers 20 each extends in a first direction (hereinafter, X-direction). The word line 30 and the select gates 40s and 40d extend over the semiconductor layers 20 in a second direction (hereinafter, Y-direction) crossing the first direction. A plurality of word lines 30 are provided between the select gate 40s and the select gate 40d.

A memory transistor MTr is provided at a portion where the word line 30 intersects a semiconductor layer 20. A select transistor STS is provided at a portion where the select gate 40s intersects the semiconductor layer 20. A select transistor STD is provided at a portion where the select gate 40d intersects the semiconductor layer 20.

The non-volatile memory device 1 further includes a source contact body 50 and drain contact bodies 60. The plurality of word lines 30 and the select gates 40 are provided between the source contact body 50 and a drain contact body 60. The source contact body 50 extends in the Y-direction on the semiconductor layer 20. The drain contact body 60 is connected to the semiconductor layer 20.

In the specification, there are a case where each select gate is distinguished as the select gate 40s or 40d, and another case where the select gates are collectively described as the select gates 40. Other elements are also described in the same manner.

As shown in FIG. 1B, the semiconductor layer 20 is provided between first insulating layers (hereinafter, shallow trench isolations, STIs 25) extending downward in the substrate 10. The semiconductor layer 20 is provided, for example, in a p-type well provided in the silicon substrate. The STIs 25 are made of silicon oxide, for example. A STI 25 electrically insulates the semiconductor layer 20a (first semiconductor layer) and semiconductor layer 20b (second semiconductor layer) adjacent to each other.

An insulating layer 13, a conductive layer 15, a metal layer 17, and an insulating layer 21 are sequentially provided on the semiconductor layer 20. The insulating layer 13 is, for example, a silicon oxide layer. The conductive layer 15 is, for example, a polysilicon layer. The metal layer 17 is, for example, made of ruthenium (Ru). The insulating layer 21 is a metal oxide layer such as hafnium oxide.

Furthermore, an insulating layer 23 is provided on the insulating layer 21 and the STIs 25. The insulating layer 23 extends in the Y-direction. The insulating layer 23 includes, for example, a metal oxide layer. The insulating layer 23 may have a multilayer structure, for example, including a silicon oxide layer provided on the insulating layer 21 and a metal oxide layer of hafnium oxide provided thereon. The word line 30 is provided on the insulating layer 23.

As shown in FIG. 1C, the memory transistors MTr and the select transistors STS and STD are provided on the semiconductor layer 20. That is, the non-volatile memory device 1 includes a NAND string including a plurality of memory transistors MTr and select transistors STS and STD.

The memory transistor MTr includes an insulating layer 13, a floating gate 70 (first conductive layer) and an insulative blocking layer 80 between the semiconductor layer 20 and the word line 30. The insulating layer 13 acts as a tunnel insulating layer. The floating gate 70 includes a conductive layer 15 and a metal layer 17, and acts as a charge storing layer.

The select transistor STS includes an insulating layer 13, a floating gate 70s (second conductive layer) and an insulative blocking layer 80 between the semiconductor layer 20 and the select gate 40s. The insulating layer 13 acts as a gate insulating layer. The floating gate 70s includes a conductive layer 15 and a metal layer 17. The floating gate 70s is electrically insulated from the select gate 40s by the insulative blocking layer 80.

The select transistor STD includes an insulating layer 13, a floating gate 70d, and an insulative blocking layer 80 between the semiconductor layer 20 and the select gate 40d. The insulating layer 13 acts as a gate insulating layer. The floating gate 70d includes a conductive layer 15 and a metal layer 17. The floating gate 70d is electrically insulated from the select gate 40d by the insulative blocking layer 80.

The non-volatile memory device 1 includes a first insulating layer (hereinafter, an interlayer insulating layer 35) covering the memory transistors MTr and the select transistors STS and STD. The interlayer insulating layer 35 includes a first portion 35a, a second portion 35b and a third portion 35c.

The first portion 35a extends between the select transistor STS and the adjacent memory transistor MTr. The first portion 35a is provided between the word line 30s and the select gate 40s. The word line 30s is located at an end on the select gate 40s side.

The second portion 35b extends between the select transistor STS and the source contact body 50. The second portion 35b is provided between the select gate 40s and the source contact body 50.

The third portion 35c extends between the select transistor STD and the adjacent memory transistor MTr. The third portion 35c is provided between the word line 30d and the select gate 40d. The word line 30d is located at the other end on the select gate 40d side.

The source contact body 50 extends in the −Z-direction in the interlayer insulating layer 35 from the upper surface 35s of the interlayer insulating layer 35. The source contact body 50 is in contact with a source region 55 at the bottom surface thereof. The source region 55 is provided in the surface of the semiconductor layer 20 on the source side of the select transistor STS. The source region 55 contains, for example, an n-type impurity with a concentration higher than the concentration of the p-type impurity in the semiconductor layer 20.

The non-volatile memory device 1 further includes a second insulating layer (hereinafter, an interlayer insulating layer 45), a source interconnection 110, and a bit line 120. The interlayer insulating layer 45 is, for example, a silicon oxide layer. The interlayer insulating layer 45 is provided on the interlayer insulating layer 35. The source interconnection 110 is provided between the interlayer insulating layer 35 and the interlayer insulating layer 45, and electrically connected to the semiconductor layer 20 through the source contact body 50. The bit line 120 is provided on the interlayer insulating layer 45 and extends in the X-direction.

The drain contact body 60 extends in the −Z-direction in the interlayer insulating layers 45 and 35. The drain contact body 60 includes a first portion 60a extending through the interlayer insulating layer 35 and a second portion 60b extending through the interlayer insulating layer 45. The drain contact body 60 is in contact with a drain region 65 at the bottom surface thereof. The drain region 65 is provided in the surface of the semiconductor layer 20 on the drain side of the select transistor STD. The drain region 65 contains, for example, an n-type impurity with a concentration higher than the concentration of the p-type impurity in the semiconductor layer 20.

As shown in FIG. 1C, the source interconnection 110 includes an opening 110a. The opening 110a is provided above the select gate 40s. The first portion 20c of the semiconductor layer 20 is located below the first portion 35a of the interlayer insulating layer 35. The first portion 20c is provided so as to be located inside the opening 110a when being viewed in the Z-direction. The second portion 20d of the semiconductor layer 20 is located below the second portion 35b of the interlayer insulating layer 35. At least a part of the second portion 20d is provided so as to be located inside the opening 110a when being viewed in the Z-direction.

That is, the first portion 20c and the part close to the select gate 40s of the second portion 20d in the semiconductor layer 20 are provided so as to be located inside the opening 110a as viewed in the −Z-direction. Thus, the floating gate 70s below the select gate 40s can be irradiated, for example, with ultraviolet light. The irradiation using the ultraviolet light may remove the excess charges from the floating gate 70s, and suppress a threshold voltage change of the select transistor STS.

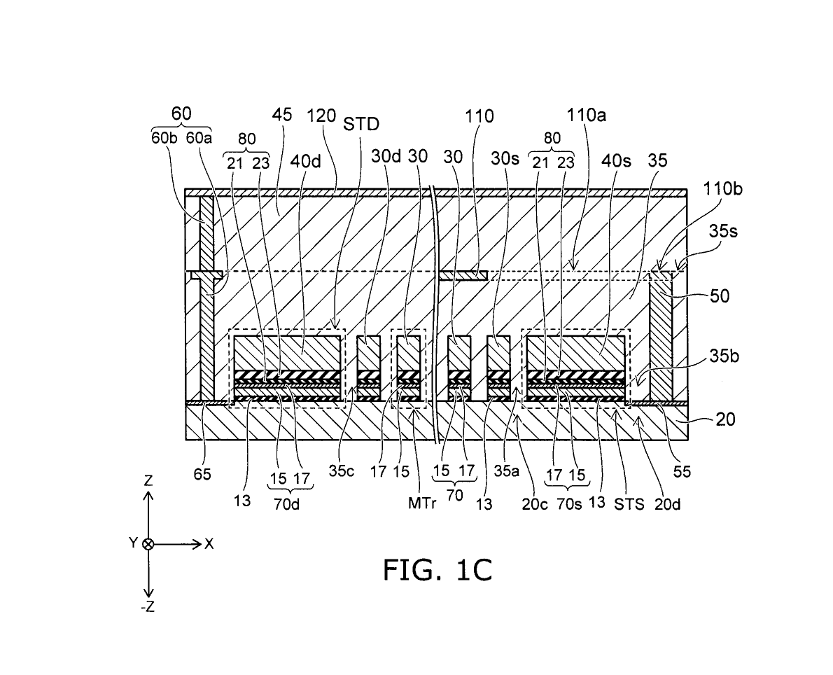

FIGS. 2A and 2B are schematic plan views showing the interconnections of the non-volatile memory device 1 according to the embodiment. FIG. 2A is a plan view showing the source interconnection 110. FIG. 2B is a plan view showing the bit lines 120.

As shown in FIG. 2A, the source interconnection 110 is formed into a lattice, and includes a first portion 110b, second portions 110c and third portions 110d. The first portion 110b extends in the Y-direction. The first portion 110b is placed on the source contact body 50 and acts as a source line. The second portions 110c each extend in the Y-direction. The second portions 110c are disposed so as to extend the source interconnection 110 in the −X-direction and the X-direction. The second portions 110c prevent the interlayer insulating layer 35 from the dishing due to CMP, while the source interconnection 110 is formed according the process described later.

The third portions 110d each extend in the X-direction and are located above the STIs 25. The third portions 110d electrically connect the first portion 110b and the second portion 110c. For example, a first portion 110b is preferably provided to have a width in the X-direction comparable to a width of the source contact body 50 in the X-direction in order to provide the opening 110a above the select gate 40s, but such a width of the first portion 110b may enlarge the electrical resistance thereof. Thus, the second portions 110c are electrically connected to the first portion 110b via the third portions 110d for reducing the electrical resistance of the source line.

As shown in FIG. 2A, the source interconnection 110 includes a plurality of openings 110a. The openings 110a are arranged in the Y-direction on both sides of the first portion 110b. The opening 110a is provided so that parts of the semiconductor layer 20 close to the select gate 40s on both sides thereof, which are the first portion 20c and the part of the second portion 20d, are not covered by the source interconnection 110 when being viewed in the −Z-direction. Thus, it becomes possible to irradiate the floating gate 70s below the select gate 40s with ultraviolet light through the opening 110a.

As shown in FIG. 2A, the source interconnection 110 is not provided above the select gate 40d. That is, the source interconnection 110 does not cover the third portion 35c of the interlayer insulating layer 35 between the select gate 40d and the adjacent word line 30d (see FIG. 1C). Thus, it is possible to irradiate the floating gate 70d below the select gate 40d with ultraviolet light without shading by the source interconnection 110.

As shown in FIG. 2B, the bit lines 120 each extend in the X-direction on the interlayer insulating layer 45. Each bit line 120 is disposed above the semiconductor layer 20 to make it easy to be electrically connected to a drain contact body 60. Each bit line 120 is electrically connected via the drain contact body 60 to any one of the semiconductor layers 20.

A space between the adjacent bit line 120a and bit line 120b has a width W_{BS} preferably equal to or wider than a width W_{S} of a space between the adjacent semiconductor layer 20a and semiconductor layer 20b (see FIG. 1B). Thereby, it becomes possible to increase the light amount reaching the floating gates 70s and 70d in the case where the floating gates 70s and 70d are irradiated from above through the space between the bit lines 120. For example, by narrowing the width W_{B} in the Y-direction of the bit line 120, it becomes possible to increase the amount of ultraviolet light reaching the floating gates 70s and 70d below the bit line 120. Furthermore, the floating gates 70s and 70d may be irradiated with a light diffracted in the space between the adjacent bit lines 120. For example, each bit line 120 is preferably disposed so as not to overlap the STI 25 between the adjacent semiconductor layers 20 when being viewed in the −Z-direction.

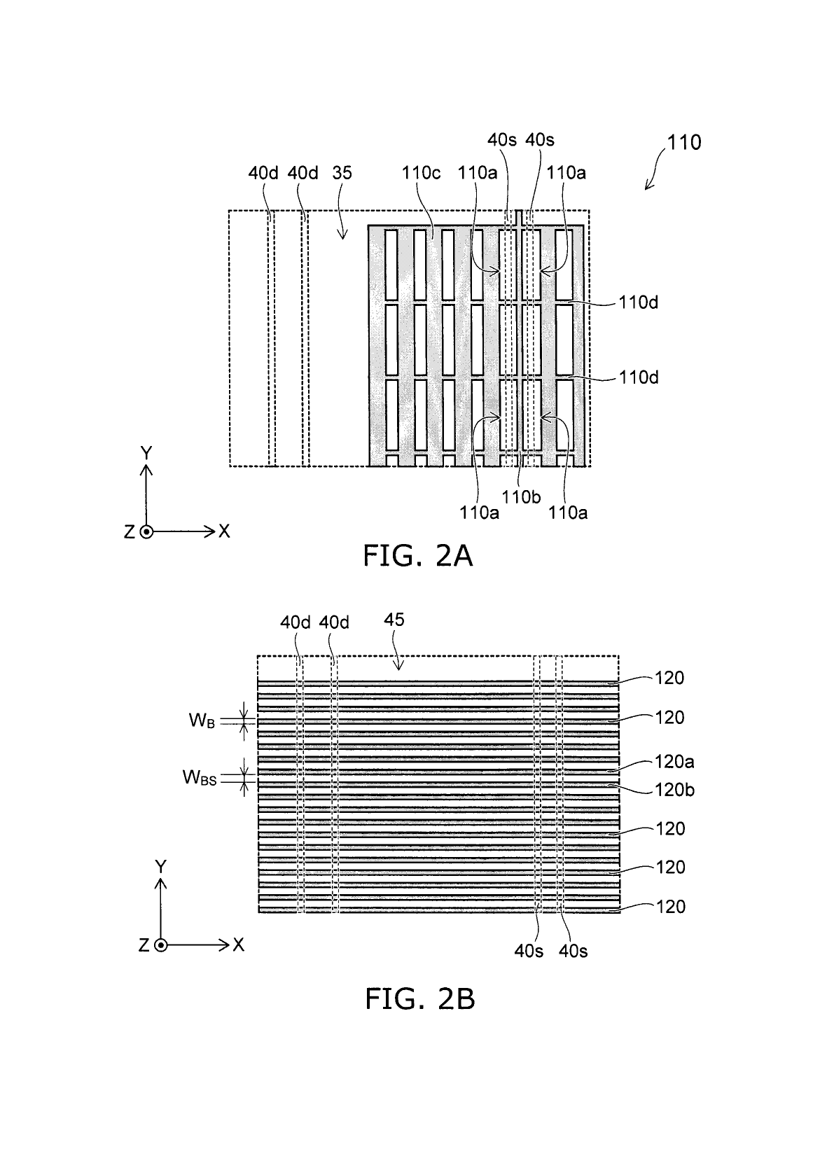

Next, a method for manufacturing the non-volatile memory device 1 according to the embodiment is described with reference to FIGS. 3A to 8. FIGS. 3A to 8 are schematic sectional views sequentially showing the manufacturing process of the non-volatile memory device 1 according to the embodiment. FIGS. 3A, 4A and 5A are schematic views showing the X-Z cross section of the substrate 10. FIGS. 3B, 4B and 5B are schematic views showing the Y-Z cross section of the substrate 10.

As shown in FIG. 3A, an insulating layer 13, a conductive layer 15, a metal layer 17, and an insulating layer 21 are sequentially formed on a substrate 10. The insulating layer 13 is, for example, a silicon oxide layer. The insulating layer 13 is formed on the substrate 10, for example, by thermal oxidation. The conductive layer 15 is, for example, a polysilicon layer. The conductive layer 15 is formed on the insulating layer 13 by CVD (chemical vapor deposition). The metal layer 17 includes, for example, ruthenium (Ru). The metal layer 17 is formed by evaporation or sputtering. The insulating layer 21 is, for example, a hafnium oxide layer. The insulating layer 21 is formed by CVD.

As shown in FIG. 3B, STI 25 are formed to extend from the upper surface of the insulating layer 21 into the substrate 10. Specifically, a trench 125 is formed, which has a depth extending from the surface of the insulating layer 21 into the substrate 10. Next, for instance, a silicon oxide layer is formed on the surface of the insulating layer 21 and embedded inside the trench 125. Then, the silicon oxide layer is removed, for example, by CMP (chemical mechanical polishing), leaving a portion embedded in the trench 125. Thus, STIs 25 are formed in the trench 125, and a semiconductor layer 20 is formed between the adjacent STIs 25.

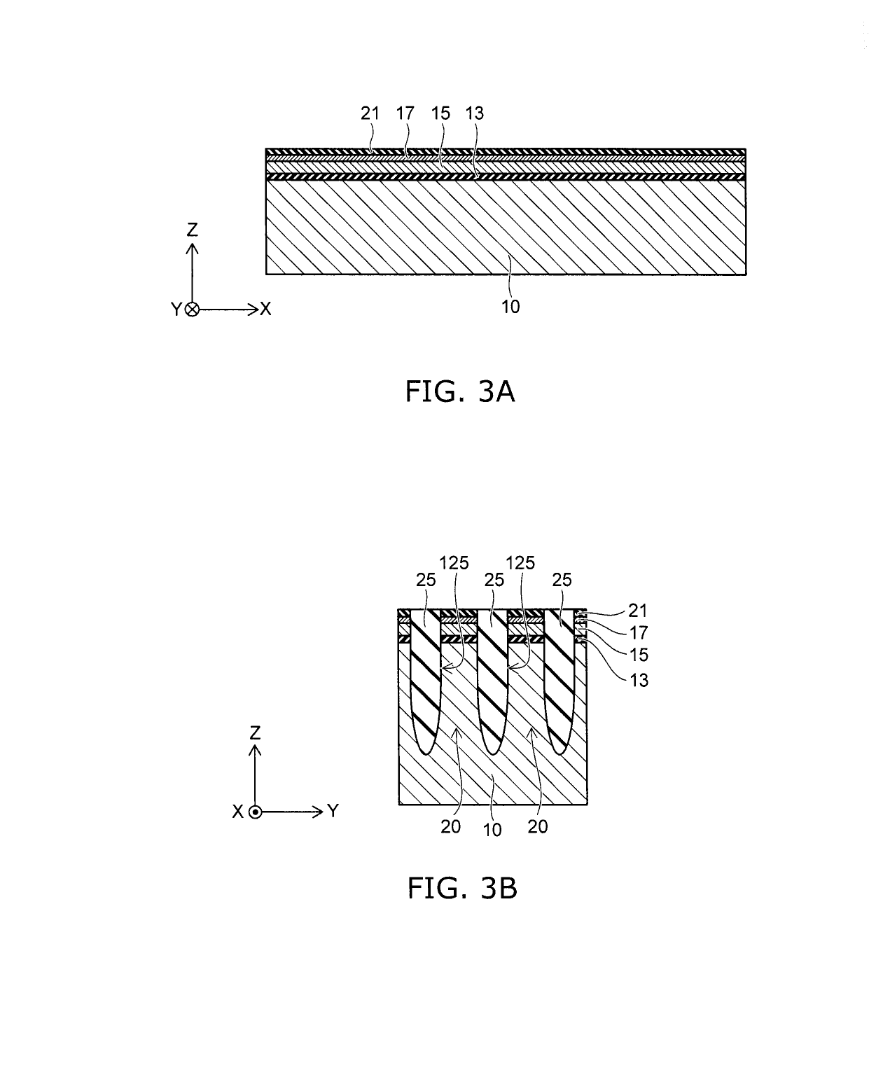

As shown in FIGS. 4A and 4B, an insulating layer 23, a conductive layer 130, and a mask layer 133 are sequentially formed on the insulating layer 21 and the STI 25. The insulating layer 23 has a stacked structure, for example, including a silicon oxide layer formed on the insulating layer 21 and a hafnium oxide layer formed thereon. The conductive layer 130 may have a stacked structure including, for example, a titanium nitride layer formed on the insulating layer 23 and a tungsten layer formed thereon. The mask layer 133 is, for example, a silicon oxide layer or silicon nitride layer. The mask layer 133 is formed into the shape of the word line 30 and the select gate 40.

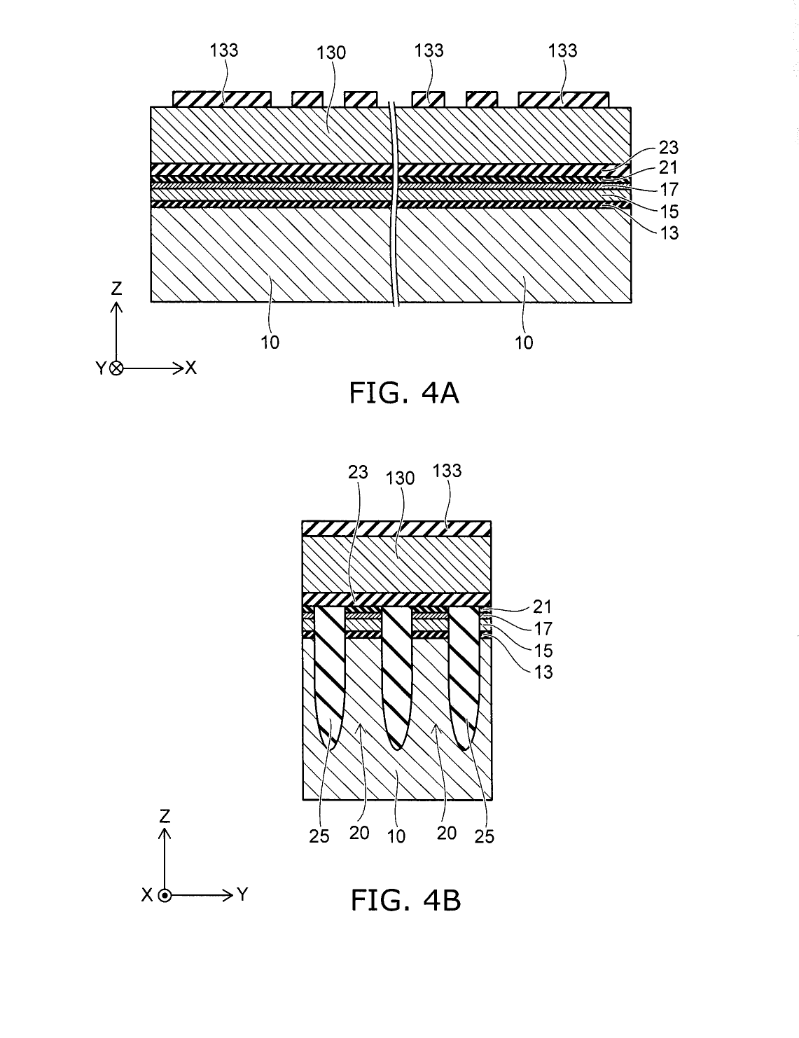

As shown in FIG. 5A, the stacked body formed on the substrate 10 is divided by etching using the mask layer 133 as an etching mask. For example, grooves 135 are formed by RIE. Thus, the conductive layer 130 is divided into word lines 30 and select gates 40s and 40d. Furthermore, a floating gate 70 is formed between the word line 30 and the semiconductor layer 20. A floating gate 70s is formed between the select gate 40s and the semiconductor layer 20. A floating gate 70d is formed between the select gate 40d and the semiconductor layer 20.

N-type impurities are ion-implanted in the semiconductor layer 20 through the grooves 135, for example, and activated by the heat treatment. Thus, a source region 55 is formed on the source side of the select gate 40s. A drain region 65 is formed on the drain side of the select gate 40d. Source/drain regions 67 are formed below a space between the word lines 30 and below a space between each select gate 40 and the word line 30.

As shown in FIG. 5B, the select gate 40s extends in the Y-direction over the floating gate 70s and the STI 25. The word lines 30 and the select gate 40d also extend in the Y-direction.

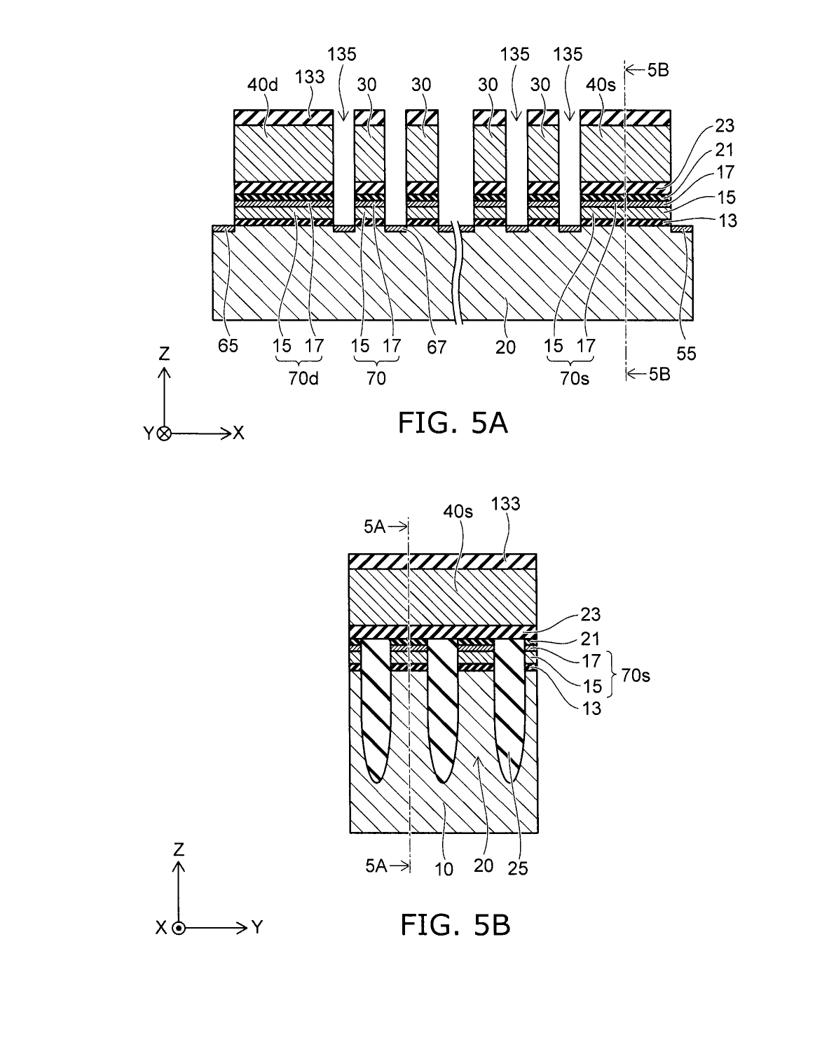

As shown in FIG. 6A, an interlayer insulating layer 35 is formed to cover the memory transistors MTr and the select transistors STS and STD. The interlayer insulating layer 35 is, for example, a silicon oxide layer formed by CVD. Furthermore, interconnection groove 140 and contact holes 150 and 160 are formed in the interlayer insulating layer 35. The contact hole 150 is in communication with the source region 55. The contact hole 160 is in communication with the drain region 65.

As shown in FIG. 6B, a source contact body 50, a first portion 60a of a drain contact body 60, and a source interconnection 110 are formed in the interconnection groove 140 and the contact holes 150 and 160. For example, a prescribed metal layer is formed on the interlayer insulating layer 35 to cover the upper surface 35s thereof, and to be embedded in the interconnection groove 140 and the contact holes 150 and 160. Then, the metal layer formed on the upper surface 35s of the interlayer insulating layer 35 is removed, for example, by CMP, leaving the portions embedded in the interconnection groove 140 and the contact holes 150 and 160. Thus, the source interconnection 110 is formed in the interconnection groove 140, and the source contact body 50 and a part of the drain contact body 60 (first portion 60a) are formed inside the contact holes 150 and 160, respectively. The source interconnection 110, the source contact body 50, and the first portion 60a may have a structure, for example, in which a titanium nitride layer and a tungsten layer are stacked.

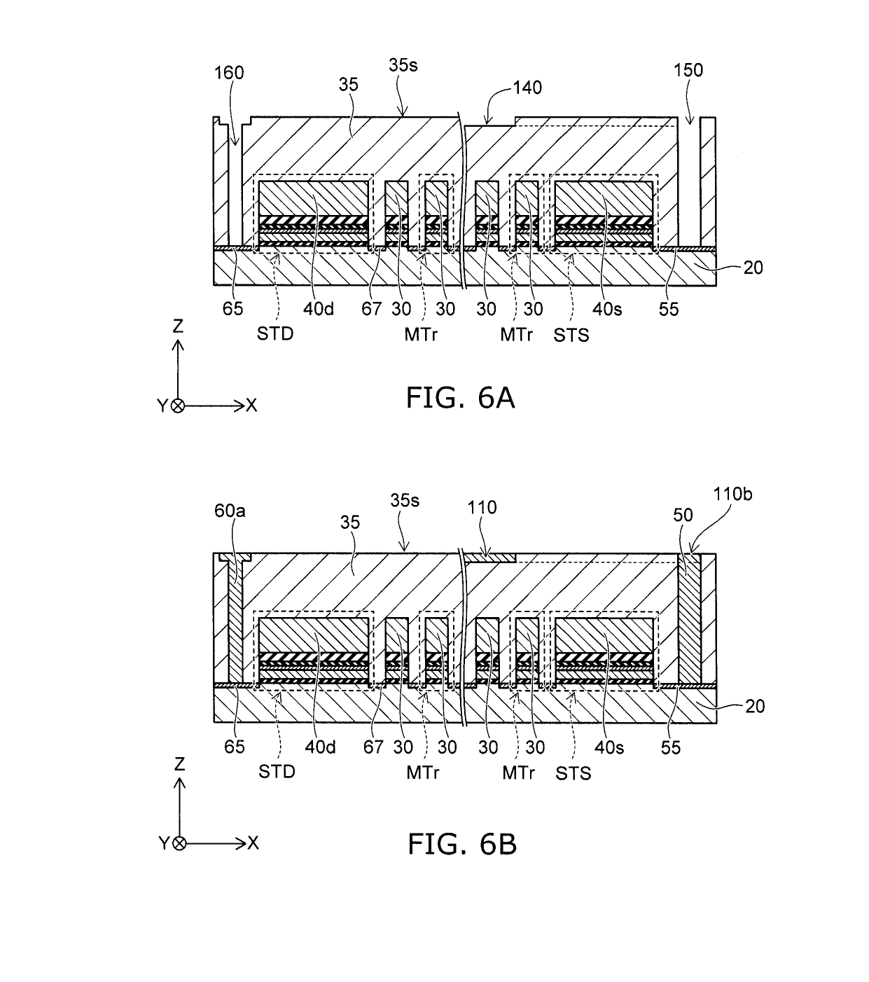

As shown in FIG. 7, an interlayer insulating layer 45 is formed on the interlayer insulating layer 35 and the source interconnection 110. The interlayer insulating layer 45 is, for example, a silicon oxide layer formed by CVD. Furthermore, the second portion 60b of the drain contact body 60 is formed in the interlayer insulating layer 45, and the bit lines 120 are formed on the interlayer insulating layer 45. The second portion 60b extends through the interlayer insulating layer 45 and is connected to the first portion 60a. The bit lines 120 are formed on the interlayer insulating layer 45, for example, by the sidewall method. Each bit line 120 is electrically connected to the drain contact body 60.

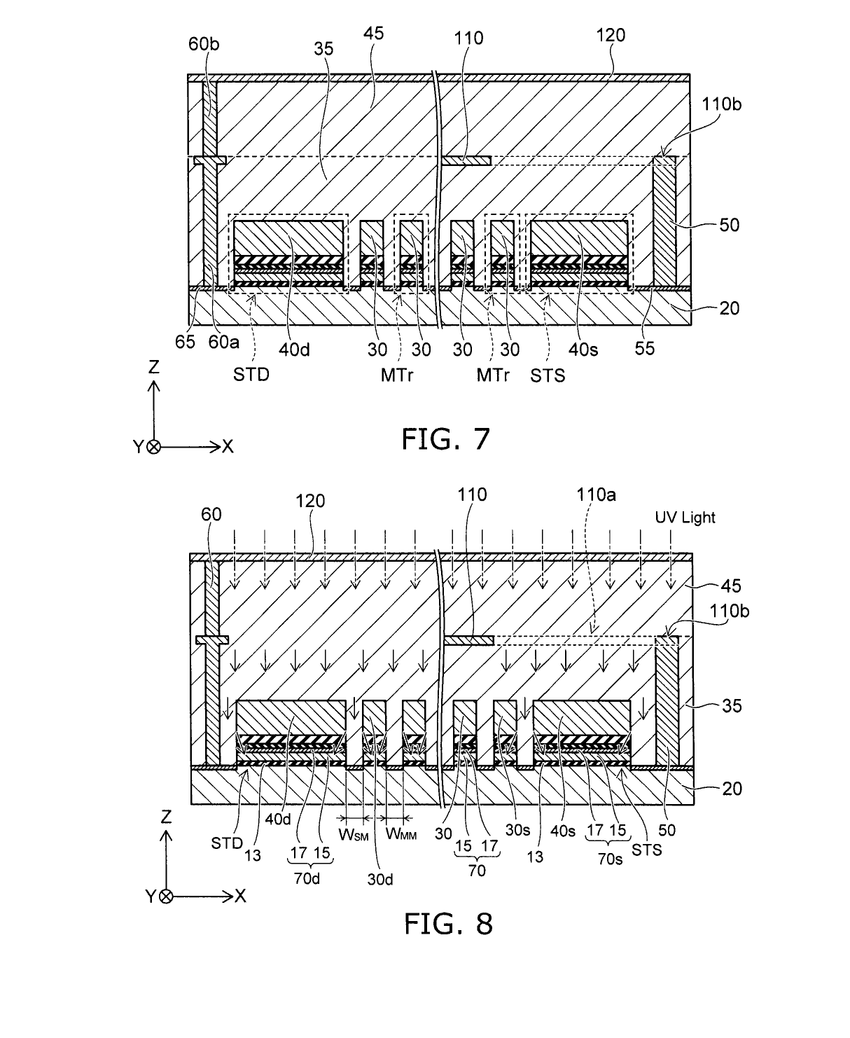

As shown in FIG. 8, the surface of the substrate 10 is irradiated with the ultraviolet light from above the bit lines 120. The ultraviolet light passes through the space between the bit lines 120 and propagates in the interlayer insulating layers 45 and 35. The interlayer insulating layers 35 and 45 are made of a material transmissive to the ultraviolet light.

The ultraviolet light passing through the space between the bit lines 120 includes not only the light propagating straight down, but also the diffracted light, making it possible to irradiate the select transistors STS and STD located below the bit lines 120.

A part of the ultraviolet light passes through the opening 110a of the source interconnection 110 and reaches the select gate 40s and its neighborhood. Furthermore, a part of the ultraviolet light propagates between the select gate 40s and the adjacent word line 30s, and reaches the floating gate 70s below the select gate 40s. That is, the ultraviolet light propagating between the select gate 40s and the adjacent word line 30s may be diffracted and reach the floating gate 70s. Then, the excess charges stored in the floating gate 70s is excited by the ultraviolet light and moves to the semiconductor layer 20 beyond the insulating layer 13. As a result, the threshold voltage of the select transistor STS may be returned, for example, to a value corresponding to the thermal equilibrium state.

Another part of the ultraviolet light propagates between the bit lines 120; then passes through a space between the select gate 40d and the adjacent word line 30; and reaches the floating gate 70d below the select gate 40d. Thus, the threshold voltage of the select transistor STD is also return, for example, to a value corresponding to the thermal equilibrium state.

For example, a space between the select gate 40 and the adjacent word line 30 is preferably formed to have a width W_{SM} wider than a width W_{MM} of a space between the word lines 30. Thus, the floating gate 70 located below the select gate 40 may be irradiated with more amount of the ultraviolet light.

The ultraviolet light also includes a light passing through a space between the select gate 40s and the source contact body 50, and reaching the floating gate 70s. The ultraviolet light also includes a light passing through a space between the select gate 40d and the drain contact body 60, and reaching the floating gate 70d.

Thus, the floating gates of the select transistors STS and STD are irradiated with ultraviolet light to suppress the variations of the threshold voltages thereof. Such irradiation with ultraviolet light is applied, for example, after completing the wafer process of the non-volatile memory device 1 and before the characteristic inspection, and improves the accuracy of the characteristic inspection.

In the non-volatile memory device 1, the source interconnection 110 has the openings 110a, which makes it possible to irradiate the space between the select gate 40s and the adjacent word line 30s with ultraviolet light, and effectively suppress the change of the threshold voltage in the select transistor STS. That is, the source interconnection 110 is formed so that a part of the semiconductor layer 20 between the select gate 40s and the adjacent word line 30s is located inside the opening 110a as viewed from above.

An upper interconnection having an opening similar to that of the source interconnection 110 may be further formed above the bit line 120. The ultraviolet radiation passes, for example, through the opening of the upper interconnection, the space between the bit lines 120 and the opening 110a of the source interconnection 110; and the floating gate 70s is irradiated therewith.

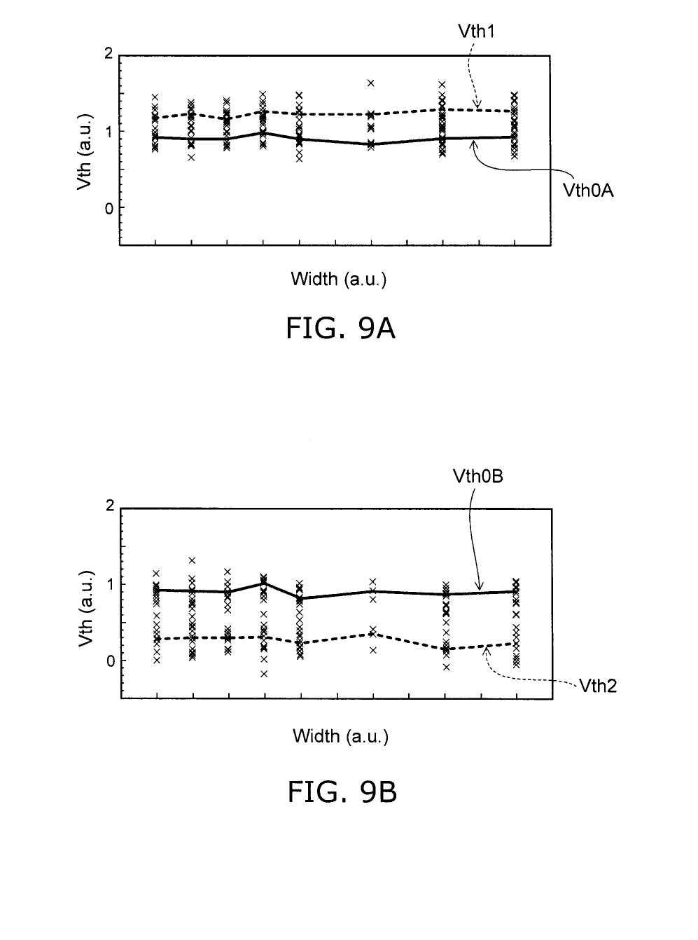

FIGS. 9A and 9B are graphs showing the characteristics of the non-volatile memory device 1 according to the embodiment. FIGS. 9A and 9B are graphs showing the threshold voltage of the select transistor before and after the ultraviolet irradiation. The vertical axis represents the threshold voltage. The horizontal axis represents the width of the select gate.

FIG. 9A shows the threshold voltages Vth0A and Vth1 of the select transistor. Vth1 represents the threshold voltage of the select transistor after the bias is applied thereto, which is the same as the data-writing bias applied to the memory transistor MTr. Vth0A represents the threshold voltage of the select transistor after the ultraviolet irradiation. As shown in FIG. 9A, Vth1 falls to Vth0A after the ultraviolet irradiation.

FIG. 9B shows the threshold voltages Vth0B and Vth2 of the select transistor. Vth2 represents the threshold voltage of the select transistor after the bias is applied thereto, which is the same as the data-erasing bias applied to the memory transistor MTr. Vth0B represents the threshold voltage of the select transistor after the ultraviolet irradiation. As shown in FIG. 9B, Vth2 rises to Vth0B after the ultraviolet irradiation.

In FIGS. 9A and 9B, Vth0A is nearly at the same level as Vth0B. That is, it is found that the threshold voltage of the select transistor is returned to the prescribed level by the ultraviolet irradiation. Furthermore, Vth0A and Vth0B exhibit no dependence on the width of the select gate. Thus, it is found that the ultraviolet irradiation effectively cancel the excess charges stored in the floating gate of the select transistor.

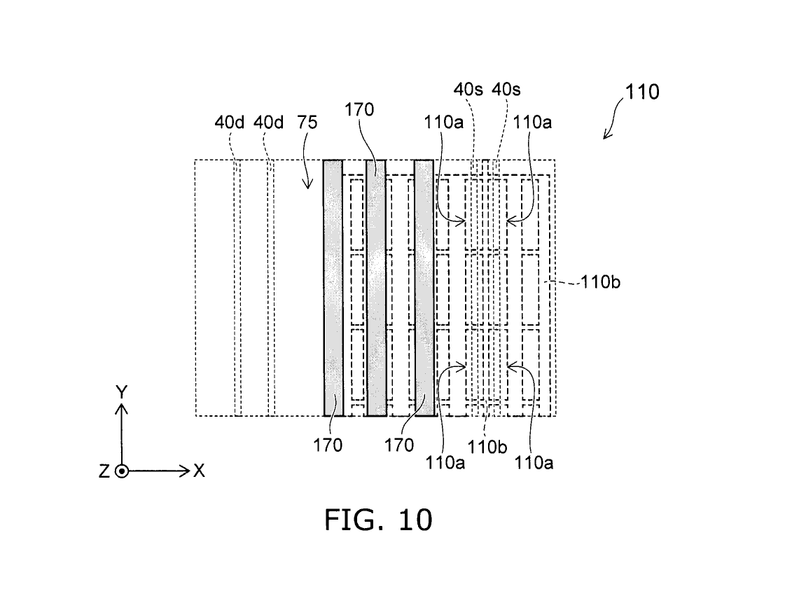

FIG. 10 is a schematic plan view showing upper interconnections 170 that are provided above the bit lines 120 (see FIG. 2B). In FIG. 10, the bit lines 120 are omitted for convenience of description. The upper interconnections 170 are provided on an interlayer insulating layer 75 that covers the bit lines 120, and extend in the Y-direction, for example. The upper interconnections 170 are provided not to overlap the openings 110a of the source interconnection 110 and the select gates 40d when being viewed in the Z-direction. Thus, it is possible to irradiate the floating gates 70s and 70d under the select gates 40 without being shaded by the upper interconnections 170.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device comprising:
a first semiconductor layer extending in a first direction;
a first electrode extending over the first semiconductor layer in a second direction crossing the first direction;
a second electrode extending over the first semiconductor layer in the second direction, the second electrode being adjacent to the first electrode;
a first insulating layer covering the first electrode and the second electrode and including a first portion extending between the first electrode and the second electrode; and
a first interconnection provided on the first insulating layer and electrically connected to the first semiconductor layer,
the first interconnection having a first opening provided above a first part of the first semiconductor layer located below the first portion of the first insulating layer.

2. The device according to claim 1, wherein the first interconnection further includes a second opening; and the first opening and the second opening are arranged in the second direction.

3. The device according to claim 1, further comprising:
a conductor adjacent to the second electrode, the conductor extending in the second direction, and electrically connecting the first semiconductor layer and the first interconnection, the second electrode being located between the first electrode and the conductor, wherein
the first insulating layer includes a second portion extending between the second electrode and the conductor;
the semiconductor layer includes a second part close to the second electrode below the second portion of the first insulating layer; and
the opening is provided above the first part and the second part of the semiconductor layer.

4. A non-volatile memory device comprising:
a first semiconductor layer extending in a first direction;
at least two first electrodes extending over the first semiconductor layer in a second direction crossing the first direction;
a second electrode adjacent to one of the at least two first electrodes, the second electrode extending over the first semiconductor layer in the second direction;
a third electrode extending over the first semiconductor layer in the second direction, the at least two first electrodes being provided between the second electrode and the third electrode, and the third electrode being adjacent to another one of the at least two first electrodes;
a first insulating layer covering the at least two first electrodes, the second electrode and the third electrode, and including a first portion and a second portion, the first portion extending between the one of the at least two first electrodes and the second electrode, and the second portion extending between the another one of the at least two first electrodes and the third electrode; and
a first interconnection provided on the first insulating layer and electrically connected to the first semiconductor layer,
the first interconnection having a first opening provided above a first part of the first semiconductor layer located below the first portion of the first insulating layer, and the first interconnection being not provided on the second portion of the first insulating layer.

5. The device according to claim 4, wherein the first interconnection further includes a second opening; and the first opening and the second opening are arranged in the second direction.

6. The device according to claim 4, further comprising:
a conductor adjacent to the second electrode, the conductor extending in the second direction, and electrically connecting the first semiconductor layer and the first interconnection, the second electrode being located between the one of the at least two first electrodes and the conductor, wherein
the first insulating layer includes a third portion extending between the second electrode and the conductor;
the semiconductor layer includes a second part close to the second electrode below the third portion of the first insulating layer; and
the opening is provided above the first part and the second part of the semiconductor layer.

7. The device according to claim 4, further comprising:
a second semiconductor layer adjacent to the first semiconductor layer, the second semiconductor layer extending in the first direction;
a second insulating layer covering the first insulating layer and the first interconnection;
a second interconnection provided on the second insulating layer and extending in the first direction; and
a third interconnection adjacent to the second interconnection on the second insulating layer, the third interconnection extending in the first direction, wherein
the second interconnection is electrically connected to the first semiconductor layer;
the third interconnection is electrically connected to the second semiconductor layer; and
a distance between the second interconnection and the third interconnection is equal to or wider than a distance between the first semiconductor layer and the second semiconductor layer.

8. The device according to claim 7, wherein the first insulating layer and the second insulating layer are transmissive to ultraviolet light.

9. The device according to claim 7, further comprising:
a conductor adjacent to the second electrode, the conductor extending in the second direction and electrically connecting the first semiconductor layer and the first interconnection, the second electrode being provided between the one of the at least two first electrodes and the conductor; and
a third insulating layer provided between the first semiconductor layer and the second semiconductor layer,
wherein the first interconnection includes:
a first portion extending in the second direction on the conductor;
a second portion adjacent to the first portion on the second insulating layer, the second portion extending in the second direction; and
a third portion extending on the second insulating layer in the first direction above the third insulating layer, and
the first opening is surrounded by the first portion, the second portion and the third portion.

10. The device according to claim 9, wherein the second interconnection and the third interconnection do not overlap the third insulating layer in a third direction orthogonal to the first direction and the second direction.

11. The device according to claim 4, further comprising:
a first conductive layer provided between the first semiconductor layer and the one of the at least two first electrodes, and electrically insulated from the first semiconductor layer and the one of the at least two first electrodes;
a second conductive layer provided between the first semiconductor layer and the second electrode, and electrically insulated from the first semiconductor layer and the second electrode; and
a third conductive layer provided between the first semiconductor layer and the third electrode, and electrically insulated from the first semiconductor layer and the third electrode,
wherein the second conductive layer and the third conductive layer include a same material as the first conductive layer.

12. The device according to claim 4, wherein a distance between the one first electrode and the second electrode is wider than a distance between adjacent ones of the at least two first electrodes.

13. A method for manufacturing a non-volatile memory device, the method comprising:
forming a stacked structure on a wafer, the stacked structure including a first semiconductor layer and floating gates, the first semiconductor layer extending in a first direction and including a source region and a drain region, and the floating gates being provided on the first semiconductor layer between the source region and the drain region and including a source side floating gate close to the source region and a drain side floating gate close to the drain region;
forming word lines, a source side select gate and a drain side select gate each extending in a second direction crossing the first direction, each of the word lines being provided on a floating gate, the source side select gate being provided on the source side floating gate, and the drain side select gate being provided on the drain side floating gate;
forming a source interconnection provided above the word lines and the source side select gate, the source interconnection being electrically connected to the source region of the first semiconductor layer and having an opening above a region between the source side select gate and a word line located at an end on the source region side;
irradiating the source side floating gate with ultraviolet light through the opening; and
irradiating the drain side floating gate with the ultraviolet radiation.

14. The method according to claim 13, wherein
the opening extends over the source region, and
the source side floating gate is irradiated with the ultraviolet light on both sides of the source side select gate in the first direction.

15. The method according to claim 13, further comprising:
forming first and second bit lines extending in the first direction above the source interconnection, wherein
the stacked structure further includes a second semiconductor layer extending in the first direction and arranged in the second direction with the first semiconductor layer, the second semiconductor layer including a source region and a drain region;
the first bit line is electrically connected to the drain region of the first semiconductor layer;
the second bit line is electrically connected to the drain region of the second semiconductor layer;
the source side floating gate is irradiated with the ultraviolet radiation through a space between the first bit line and the second bit line, and through the opening of the source interconnection; and
the second floating gate is irradiated with the ultraviolet radiation through the space between the first bit line and the second bit line.

16. The method according to claim 13, wherein
the source side floating gate is irradiated with the ultraviolet light diffracted between the word line located at the end on the source region side and the source side select gate, and
the drain side floating gate is irradiated with the ultraviolet light diffracted between a word line located at an end on the drain region side and the drain side select gate.

17. The method according to claim 15, further comprising:
forming an upper interconnection above the first and second bit lines, the upper interconnection having another opening above the region between the word line located at the end on the source region side and the source side select gate, the upper interconnection being not located above a region between the word line located at an end on the drain region side and the drain side select gate,
wherein the source side floating gate is irradiated with the ultraviolet light through the another opening of the upper interconnection, through the space between the first and second bit lines, and through the opening of the source interconnection.
